(19) United States
(12) Patent Application Publication
(10) Pub. No.: US 2025/0167043 A1
(43) Pub. Date: May 22, 2025

(54) INTERCONNECT STRUCTURE, METHOD OF MANUFACTURING SAME, AND ELECTRONIC DEVICE INCLUDING SAME

(71) Applicant: SAMSUNG ELECTRONICS CO., LTD., Suwon-si (KR)

(72) Inventors: Keun Wook SHIN, Suwon-si (KR); Sangwon KIM, Suwon-si (KR); Joonseok KIM, Suwon-si (KR); Joonyun KIM, Suwon-si (KR); Daejin YANG, Suwon-si (KR); Chang Seok LEE, Suwon-si (KR); Tae Won JEONG, Suwon-si (KR); GIYOUNG JO, Suwon-si (KR); LUHING HU, Suwon-si (KR)

(21) Appl. No.: 18/948,843

(22) Filed: Nov. 15, 2024

(30) Foreign Application Priority Data
Nov. 17, 2023 (KR) 10-2023-0159763

(51) Int. Cl. H01L 21/768; H01L 23/522; H01L 23/532

(52) U.S. Cl. CPC H01L 21/7682; H01L 21/76843; H01L 21/76877; H01L 23/5226; H01L 23/53238; H01L 23/53266

(57) ABSTRACT

An interconnect structure including a dielectric layer having a trench structure; a conductive wiring including a metal compound represented by Chemical Formula 1 disposed within the trench structure (conductive interconnect), and air gap disposed between the conductive wiring. The trench structure has a line width of less than or equal to about 10 nm and an aspect ratio of greater than or equal to about 3.

MXₐ Chemical Formula 1

In Chemical Formula 1, M is at least one metal of Zr, Nb, Cu, Ru, Al, Co, W, Mo, Ti, Ta, Ni, Pt, Cr, Rh, Ir, Pd, or Os, X is at least one element of C, N, P, As, S, Se, or Te, and a is a number determined by the stoichiometry of M and X.

### CROSS-REFERENCE TO RELATED APPLICATION

This application claims priority to Korean Patent Application No. 10-2023-0159763 filed in the Korean Intellectual Property Office on Nov. 17, 2023, and all the benefits accruing therefrom under 35 U.D.C. § 119, the entire content of which is herein incorporated by reference.

### BACKGROUND

### 1. Field

The present disclosure relates to an interconnect structure, a method for manufacturing the interconnect structure, and an electronic device including the interconnect structure.

### 2. Description of the Related Art

In order to provide high-density, high-performance semiconductor devices, efforts are continuing to reduce the line width or thickness of metal wiring. By reducing the line width, e.g., by reducing a thickness of metal wiring, the number of semiconductor chips integrated per unit wafer can be increased. Additionally, by reducing the thickness of the metal wiring, one would expect the capacitance of the line (wire) to decrease, and thus the speed of the signal passing through the wiring would increase.

On the other hand, as the line width or thickness of the metal wiring decreases, the resistance of the wire can rapidly increase, and therefore, reducing the resistance of the metal wire can become more important than a reduction in capacitance or an increase in chip density. Current wiring technology has a problem in that resistivity increases significantly due to grain-boundary scattering and/or surface-roughness scattering as line widths of the wires are reduced. Additionally, since deterioration may occur due to oxidation occurring at the metal/oxide interface or exposed metal surface, there is much interest in a technology to reduce the resistance of the wire structure while preventing metal oxidation of the interface or the wire.

### SUMMARY

An embodiment provides an interconnect structure that can minimize oxidation of metal wiring as well as relatively reduce an expected increase in resistance due to a decrease in line width of the metal wiring.

An embodiment provides a method of manufacturing the interconnect structure.

An embodiment provides an electronic device including the interconnect structure.

According to an embodiment, an interconnect structure includes a dielectric layer including a trench structure; a conductive wiring (conductive interconnect) including a metal compound represented by Chemical Formula 1 disposed within the trench structure, e.g., the metal compound would partially or completely fill the trench structure; and an air gap disposed between the conductive wiring, wherein the trench structure has a line width of less than or equal to about 10 nm and an aspect ratio of greater than or equal to about 3:

MXₐ Chemical Formula 1
wherein, in Chemical Formula 1,
M is at least one metal of Zr, Nb, Cu, Ru, Al, Co, W, Mo, Ti, Ta, Ni, Pt, Cr, Rh, Ir, Pd, or Os, X is at least one element of C, N, P, As, S, Se, or Te, and a is a number determined by the stoichiometry of M and X.

The dielectric layer may include a dielectric with a dielectric constant of less than or equal to about 3.6.

The dielectric layer may include a metal oxide, a carbon-doped metal oxide, a metal carbide, a hydrogenated metal carbide, a metal nitride, a metal oxynitride, or a combination thereof.

The dielectric layer may include AlO_{z} (0<z≤3/2, for example, Al₂O₃), AlN, ZrOₓ (0<x≤2), HfOₓ (0<x≤2), SiO₂, SiCO, SiCN, SION, SiCOH, AlSiO, BN, or a combination thereof.

The dielectric layer may include a Group 3A (Group 13) element, a Group 4A (Group 14) element, a Group 4B (Group 4) element, or a combination thereof.

The air gap disposed between the conductive wiring may be positioned in the dielectric layer between the conductive wiring.

A width of the air gap may be in a range of about 2 nm to about 12 nm.

A depth of the air gap may be equal to or less than a depth of the conductive wiring.

A ratio of the width of the air gap to the line width of the conductive wiring may be about 1.1:1 to about 4:1.

The interconnect structure may further include a cap layer on an upper portion of the conductive wiring.

A barrier layer may further be included on at least one surface of the trench structure between the dielectric layer and the conductive wiring.

The barrier layer may include a metal, an alloy of a metal, a metal oxide, a metal nitride or a combination thereof.

A liner layer may further be included on at least a surface of the trench structure between the dielectric layer and the conductive wiring.

The interconnect structure may include a plurality of interconnect lines and a via connecting a lower interconnect line and an upper interconnect line, and the via may include the metal compound of Chemical Formula 1.

According to another embodiment, an interconnect structure includes a first dielectric layer including a trench structure; a conductive wiring including a metal compound represented by Chemical Formula 1 disposed within the trench structure; and a second dielectric layer disposed on the first dielectric layer, wherein the trench structure has a line width of less than or equal to about 10 nm and an aspect ratio of greater than or equal to 3.

The first dielectric layer may include a first dielectric with a dielectric constant of less than or equal to about 3.6, and the second dielectric layer may include a second dielectric different from the first dielectric.

The first dielectric layer may include a metal oxide, a carbon-doped metal oxide, a metal carbide, a hydrogenated metal carbide, a metal nitride, a metal oxynitride, or a combination thereof.

The first dielectric layer may include AlO_{z} (0<z≤3/2, for example, Al₂O₃), AlN, ZrOₓ (0<x≤2), HfOₓ (0<x$2), SiO₂, SiCO, SiCN, SION, SiCOH, AlSiO, BN, or a combination thereof.

The first dielectric layer may include a Group 3A (Group 13) element, a Group 4A (Group 14) element, a Group 4B (Group 4) element, or a combination thereof.

The second dielectric layer may include AlO_{z} (0<z≤3/2, for example, Al₂O₃), AlN, ZrOₓ (0<x≤2), HfOₓ (0<x≤2), SiO₂, SiCO, SiCN, SION, SiCOH, AlSiO, BN, or a combination thereof.

The interconnect structure may further include a cap layer on an upper layer of the conductive wiring.

A barrier layer may further be included on at least a surface of the trench structure between the first dielectric layer and the conductive wiring.

The barrier layer may include a metal, an alloy of a metal, a metal oxide, a metal nitride, or a combination thereof.

A liner layer may further be included on at least a surface of the trench structure between the first dielectric layer and the conductive wiring.

The interconnect structure may include a plurality of interconnect lines and a via connecting a lower interconnect line and an upper interconnect line, and the via may include the metal compound of Chemical Formula 1.

According to another embodiment, a method for manufacturing an interconnect structure includes:
i. providing a first dielectric layer including a trench structure;
ii a. adding a metal (M), or a metal (M)-containing precursor, within the trench structure, heating the metal or metal-containing precursor to a reaction temperature, and adding an X-containing precursor under an inert atmosphere to the metal or metal-containing precursor to form a conductive wiring including a metal compound of Chemical Formula 1;
iii. removing all or a portion of the first dielectric layer to form an air gap, e.g., between the conductive wiring or the dielectric layer and the conductive wiring; and
iv. forming a second dielectric layer on the conductive wiring or the first dielectric layer.

According to another embodiment, a method for manufacturing an interconnect structure includes:
i. providing a first dielectric layer including a trench structure;
ii b. adding a metal (M)-containing precursor and an X-containing precursor within the trench structure under an inert atmosphere, and heating the metal-containing precursor and the X-containing precursor to a reaction temperature to form a conductive wiring including a metal compound of Chemical Formula 1;
iii. removing all or a portion of the first dielectric layer to form an air gap, e.g., between the conductive wiring or the dielectric layer and the conductive wiring; and
forming a second dielectric layer on the conductive wiring or the first dielectric layer.

According to another embodiment, a method for manufacturing an interconnect structure includes
adding a metal (M)-containing precursor and an X-containing precursor on a dielectric layer under an inert atmosphere to form a conductive layer including a metal compound of Chemical Formula 1, and
patterning the conductive layer, and forming a dielectric layer on the patterned conductive layer to form a conductive wiring.

According to another embodiment, a method for manufacturing an interconnect structure includes:
i. providing a first dielectric layer including a trench structure;
ii. adding a metal (M), or a metal (M)-containing precursor, within the trench structure, heating the metal or metal-containing precursor to a reaction temperature, and adding an X-containing precursor under an inert atmosphere to the metal or metal-containing precursor to form a conductive wiring including a metal compound of Chemical Formula 1, and
forming a second dielectric layer on an upper portion of the first dielectric layer.

According to another embodiment, a method for manufacturing an interconnect structure includes:
providing a first dielectric layer with a trench structure;
adding a metal (M)-containing precursor and an X-containing precursor within the trench structure under an inert atmosphere, and heating the metal-containing precursor and the X-containing precursor to a reaction temperature to form a conductive wiring including a metal compound of Chemical Formula 1; and
forming a second dielectric layer on an upper portion of the first dielectric layer.

Another embodiment provides an electronic device including the interconnect structure.

The electronic device may be a transistor, a capacitor, a diode, or a resistor.

The interconnect structure can prevent or reduce an increase in resistance due to grain-boundary scattering and/or surface-roughness scattering due to a decrease in the line width of a metal wiring and/or can prevent oxidation of a conductive wiring.

### BRIEF DESCRIPTION OF THE DRAWINGS

FIGS. 1 to 5 are cross-sectional views of interconnect structures according to embodiments.

FIG. 6 is a cross-sectional view of an electronic device according to an embodiment.

FIG. 7 is a cross-sectional view of an electronic device according to an embodiment.

FIG. 8 is X-ray diffraction spectra of stacked structures according to Examples 1 and 2.

FIG. 9 is a plot of normalized resistance according to film thickness of a stacked structure of Example 2 and a stacked structure according to Comparative Example 1.

### DETAILED DESCRIPTION

Hereinafter, example embodiments of the present disclosure will be described in detail so that a person skilled in the art would understand the same. This disclosure may, however, be embodied in many different forms and is not construed as limited to the example embodiments set forth herein. Moreover, the terminology used herein is used to describe embodiments only and is not intended to limit the present disclosure.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein.

As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. “At least one” is not to be construed as limiting “a” or “an.” “Or” means “and/or.” As used herein, the term “and/or” includes any and all combinations of one or more of the associated listed items.

As used herein, terms such as “comprise,” “comprise,” “includes”, “with” or “have” are intended to designate the presence of implemented features, numbers, steps, components, or a combination thereof, but not one or more other features, numbers, steps, components, or combinations thereof should be understood as not excluding in advance the existence or possibility of addition.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. In contrast, when an element is referred to as being “directly on” another element, there are no intervening elements present.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±5%, ±3%, or ±1% of the stated value.

Relative terms, such as “downward,” “lower,” or “bottom,” and “upward,” “upper,” or “top,” may be used herein to describe one element's relationship to another element as illustrated in the drawings. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Example embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In addition, “layer” herein includes not only a shape formed on the whole surface when viewed from a plan view, but also a shape formed on a partial surface.

The connections or connection members of lines between components shown in the drawings exemplify functional connections and/or physical or circuit connections, and in actual devices, may be represented as various functional connections, physical connections, or circuit connections.

As used herein, “at least one of A, B or C,” “one of A, B, C, or a combination thereof” and “one of A, B, C, and a combination thereof” refer to each component and refers to any combination (e.g., A; B; C; A and B; A and C; B and C; or A, B, and C).

Herein, “a combination thereof” means a mixture of components, a laminate, a composite, an alloy, a blend, and the like.

Herein, “metal” is interpreted as a concept that includes metals and metalloids (semimetals).

Hereinafter, an interconnect structure according to an embodiment will be described with reference to the attached drawings.

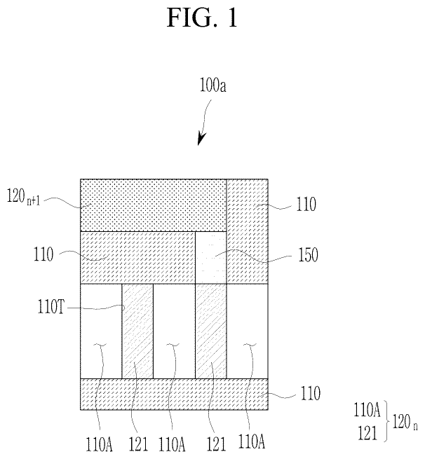

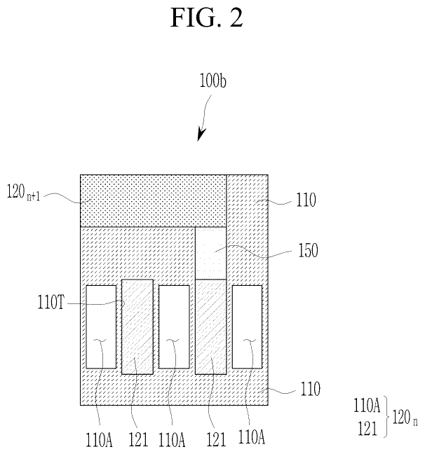

FIGS. 1 and 2 are cross-sectional views of an interconnect structure according to embodiments.

Referring to FIGS. 1 and 2, the interconnect structures 100a and 100b includes a dielectric layer 110 having a trench structure 110T and including an air gap 110A therein, and a conductive wiring 121 including a metal compound disposed, e.g., filled, within the trench structure 110T.

The interconnect structures 100a and 100b can be provided on a substrate (not shown) to constitute an electronic device. For example, the electronic device may include a DRAM or a logic device, and in this case, the interconnect structures 100a and 100b may be applied to a BEOL (Back End Of Line) structure of the DRAM or the logic device. In addition, the interconnect structures 100a and 100b can be applied to various electronic devices.

The substrate may be a semiconductor substrate. For example, the substrate may include a Group IV semiconductor material, a Group III-V semiconductor compound, or a Group II-VI semiconductor compound. That is, the substrate may include a Group IV semiconductor material including at least one of Si, Ge, Sn, or C, a Group III-V compound semiconductor material in which at least one of B, Ga, In, or Al is combined with at least one of N, P, As, Sb, S, Se, or Te, or a Group II-VI compound semiconductor material in which at least one of Be, Mg, Cd, or Zn is combined with at least one of O, S, Se, or Te. As specific examples, the substrate may include Si, Ge, SiC, SiGe, SiGeC, Ge alloy, GaAs, InAs, InP, or the like. However, this is only an example, and various other semiconductor materials can be used as substrates.

The substrate may include, for example, a Silicon-On-Insulator (SOI) substrate or a Silicon Germanium-On-Insulator (SGOI) substrate. Additionally, the substrate may include a non-doped semiconductor material or a doped semiconductor material.

The substrate may include at least one semiconductor device (not shown). The semiconductor device may include, for example, at least one of a transistor, a capacitor, a diode, and a resistor. However, the present disclosure is not limited thereto.

The dielectric layer 110 may be formed on the substrate. This dielectric layer 110 may have a single-layer structure or a multi-layer structure in which different dielectric materials are laminated. The dielectric layer 110 may be an intermetallic dielectric (IMD) layer.

The dielectric layer 110 may include, for example, a low-k dielectric material. For example, the dielectric layer 110 may include a dielectric with a dielectric constant of less than or equal to about 3.6, for example, less than or equal to about 3.5, less than or equal to about 3.3, less than or equal to about 3.0, less than or equal to about 2.8, or less than or equal to about 2.7, and greater than or equal to about 0.01, for example, greater than or equal to about 0.02, greater than or equal to about 0.03, greater than or equal to about 0.04, or greater than or equal to about 0.05. Here, the low-k material can mean a material with a lower dielectric constant (k) than silicon oxide (SiO₂).

As the size of the device decreases, the spacing between conductive wirings 121 may decrease. Accordingly, the volumetric size or dimension of the dielectric layer 110 area disposed between the conductive wirings 121 is reduced, which may cause crosstalk that affects the performance of the device. However, by using a low-k material in the dielectric layer 110, parasitic capacitance affecting the performance of the device can be reduced, and also fast switching speed and low heat dissipation can be achieved.

In an embodiment, the dielectric layer 110 may include a metal oxide, a carbon-doped metal oxide, a metal carbide, a hydrogenated metal carbide, a metal nitride, a metal oxynitride, or a combination thereof. The dielectric layer 110 may include AlO_{z} (0<z≤3/2, for example, Al₂O₃), AlN, ZrOₓ (0<x≤2), HfOₓ (0<x≤2), SiO₂, SiCO, SiCN, SiON, SiCOH, AlSiO, BN, or a combination thereof.

The dielectric layer 110 may include a Group 3A (Group 13) element, a Group 4A (Group 14) element, a Group 4B (Group 4) element, or a combination thereof.

The dielectric layer 110 can be formed on a substrate through a deposition process used in a general semiconductor manufacturing process, such as chemical vapor deposition (CVD), plasma enhanced CVD (PECVD), or spin coating.

The trench structure 110T can be formed in the dielectric layer 110 to a predetermined depth. Such a trench structure 110T can be formed, for example, using well known photolithography process and/or an etching process.

The trench structure 110T can have a line width of less than or equal to about 10 nanometers (nm), for example, less than or equal to about 9 nm, less than or equal to about 8 nm, less than or equal to about 7 nm, or less than or equal to about 6 nm, and greater than or equal to about 1 nm. The trench structure 110T may have an aspect ratio of greater than or equal to about 3, for example, greater than or equal to about 4, greater than or equal to about 5, or greater than or equal to about 6. The aspect ratio means the depth of the trench structure 110T divided by the width.

In order to increase the integration of semiconductor devices, the size of semiconductor devices is gradually decreasing, and accordingly, the line width of conductive wiring must also decrease. There is a problem, however, that the smaller linewidths can result in significant resistivity increases due to grain-boundary scattering and/or surface-roughness scattering, e.g., as the thickness of the conductive wiring is reduced. This increase in resistivity may cause defects in the conductive wiring by causing electromigration phenomena, which may damage the conductive wiring. Here, electromigration refers to the movement of matter by the continuous movement of ions within a conductor resulting from the transfer of momentum between conducting electrons and atomic nuclei within the metal. Even if the line width of the interconnect structure decreases and the aspect ratio increases, the increase in resistance can be alleviated by including a metal compound having conductivity described later in the conductive wiring. These metal compounds do not exhibit a large increase in resistance as the thickness decreases, so when used to provide the conductive wiring 121, a rapid increase in resistance can be prevented, minimized, or reduced.

The metal compound may be represented by Chemical Formula 1:

MXₐ Chemical Formula 1

In Chemical Formula 1,
M is at least one metal of Zr, Nb, Cu, Ru, Al, Co, W, Mo, Ti, Ta, Ni, Pt, Cr, Rh, Ir, Pd, or Os, X is at least one element of C, N, P, As, S, Se, or Te, a is a number determined by the stoichiometry of M and X, and a may be in the range of 0.1 to 10, e.g., 0.1 to 6.

The metal compound represented by Chemical Formula 1 may be a monocrystalline or polycrystal compound, and may be a carbide, a nitride, a phosphide, an arsenide, a sulfide, a selenide, or a telluride including at least one metal selected from Zr, Nb, Cu, Ru, Al, Co, W, Mo, Ti, Ta, Ni, Pt, Cr, Rh, Ir, Pd, or Os. Examples of the metal compound may include titanium nitride (TiN), tantalum nitride (TaN), ruthenium nitride (RUN), tungsten nitride (WN), aluminum nitride (AlN), IrTaN, TiSiN, TiAlN, NbN, MoN, TaP, MoP, WP, NbP, TaAs, NbAs, etc.

The metal compound does not show a large increase in resistance due to a decrease in line width compared to metals conventionally used in conductive wiring. The metal compound may have a lower sensitivity to oxidation compared to conventional conductive wiring, thereby improving oxidation stability and process stability.

The conductive wiring 121 may have a single-layer structure or a multi-layer structure in which different materials are stacked (or laminated).

The dielectric layer 110 may include an airgap 110A. When the air gap 110A is arranged in adjacent to or between the conductive wiring 121, the dielectric constant of the dielectric layer 110 is lowered, and thus interference between adjacent conductive wiring 121 can be prevented and signal delay (RC delay) of the device can be prevented, minimized, or reduced.

The air gap 110A may be formed by completely etching the dielectric layer (IMD) 110 between the conductive wirings 121 as in FIG. 1, or the air gap 110A may be formed by partially etching as in FIG. 2. In the latter aspect, the air gap disposed between the conductive wiring may be positioned in the dielectric layer between the conductive wiring. The above etching can form an air gap 110A by forming a space of a desired depth by etching an exposed portion of the dielectric layer 110 after forming a photoresist pattern and then forming an upper dielectric layer (interlayer insulating layer) with little or no filling of the formed space. The etching may be dry or wet etching.

When the entire dielectric layer 110 is etched and removed to form an upper dielectric layer, the air gap 110A may be in contact with the conductive wiring 121 on both side surfaces of the wiring, and when a portion of the dielectric layer 110 is etched and removed to form an upper dielectric layer, the air gap 110A may exist as an isolated space (volume) within the dielectric layer 110.

In another embodiment, the air gap 110A illustrated in FIG. 1 may be formed by forming a conductive wiring layer including a metal compound of Chemical Formula 1, patterning the conductive wiring layer, and then forming an upper dielectric layer.

The width of the above air gap 110A, as indicated in the cross-sectional view of FIGS. 1 and 2 from left to right, may be in a range of about 2 nm to about 12 nm. Accordingly, within the above range, the width of the air gap 110A may be greater than or equal to about 2.5 nm, greater than or equal to about 3 nm, or greater than or equal to about 3.5 nm, and less than or equal to about 11 nm, less than or equal to about 10 nm, less than or equal to about 9 nm, or less than or equal to about 8 nm. Within the range, interference between conductive wiring 121 can be minimized or prevented and signal delay (RC delay) of the device can be minimized or prevented.

The depth of the air gap 110A, as indicated in the cross-sectional view of FIGS. 1 and 2 from top to bottom, may be equal to or less than the depth of the conductive wiring 121, for example, less than or equal to about 90% of the depth of the conductive wiring 121, for example, less than or equal to about 80%, or less than or equal to about 70%, and greater than or equal to about 10% of the depth of the conductive wiring 121, for example, greater than or equal to about 20%, of the depth of the conductive wiring 121. Accordingly, within the above range, a dielectric constant of the dielectric layer 110 can be reduced to a sufficient range.

A ratio of the width of the air gap 110A to the line width of the conductive wiring 121 may be greater than or equal to about 1.1:1, for example, greater than or equal to about 1.2:1, greater than or equal to about 1.3:1, greater than or equal to about 1.4:1, or greater than or equal to about 1.5:1, and less than or equal to about 5:1, for example, less than or equal to about 4:1, or less than or equal to about 3:1. Within the above range, the resistance of the conductive wiring 121 can be reduced to a sufficient range.

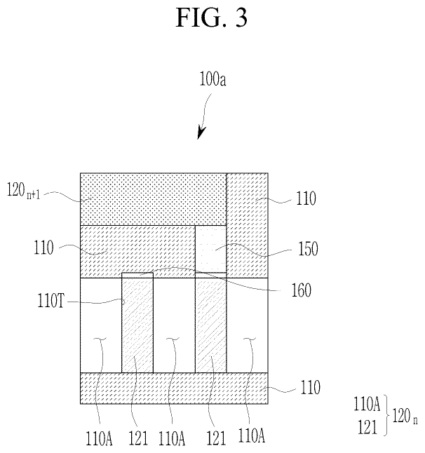

FIG. 3 is a cross-sectional view of an interconnect structure according to one embodiment. The interconnect structures 100a and 100b may further include a cap layer 160 on the upper portion of the conductive wiring 121. The interconnect structure further including a cap layer 160 on the upper portion of the conductive wiring 121 of the interconnect structure 100a is illustrated in FIG. 3. This cap layer 160 can reduce the resistance of the conductive wiring 121 and prevent electrical deterioration of the conductive wiring 121. The cap layer 160 may be arranged to cover a portion of the upper surface of the conductive wiring 121 and a portion of an upper surface of the dielectric layer 110.

The cap layer 160 may include Co, Ru, Ta, SiN, SiON, graphene, hexagonal boron nitride (h-BN), amorphous boron nitride (α-BN), AlO_{z} (0<z≤3/2), AlN, or a combination thereof.

The cap layer 160 may have a single-layer structure or a multi-layer structure in which different materials are stacked.

The thickness of the cap layer 160 may be in a range of about 1 nm to about 20 nm, about 1 nm to about 10 nm, about 1 nm to about 5 nm, or about 1 nm to about 3 nm.

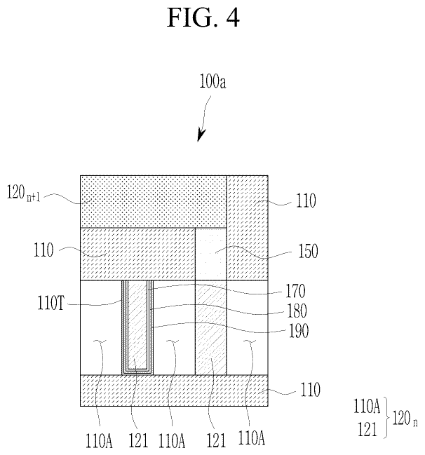

FIG. 4 is a cross-sectional view of an interconnect structure according to an embodiment. A passivation layer may be arranged between the dielectric layer 110 and the conductive wiring 121 along both side surfaces, and optionally, the lower surface of the trench structure 110T. An interconnect structure further including a passivation layer 170 formed on both side surfaces, and the lower surface of the trench structure 110T of the conductive wiring 121 of the interconnect structure 100a illustrated in FIG. 1 is illustrated in FIG. 4. When the dielectric layer 110 existing between the conductive wirings 121 is completely removed, the air gap 110A and the passivation layer 170 can come into contact.

The passivation layer 170 may include an inorganic oxide or an inorganic nitride, and specifically may include AlO_{z} (0<z≤3/2, for example, Al₂O₃), AlN, ZrO₂, HfOₓ (0<x≤2), SiO₂, SiCO, SiCN, SiON, SiCOH, AlSiO, or a combination thereof.

The passivation layer 170 may have a single-layer structure or a multi-layer structure in which different materials are stacked.

The passivation layer 170 may have a thickness of less than or equal to about 30 nm, for example, less than or equal to about 25 nm, less than or equal to about 20 nm, less than or equal to about 15 nm, less than or equal to about 10 nm, less than or equal to about 9 nm, less than or equal to about 8 nm, less than or equal to about 7 nm, or less than or equal to about 6 nm, and may have a thickness of greater than or equal to about 0.1 nm. Within the above range, diffusion of a substance into the conductive wiring 121 may be minimized or prevented and oxidation of the conductive wiring 121 may be minimized or prevented.

The ratio of the line width of the conductive wiring 121 to the thickness of the passivation layer 170 may be in the range of about 1:0.01 to about 1:3. The ratio of the thickness of the passivation layer 170 to the line width of the conductive wiring 121 may be, for example, greater than or equal to about 0.01:1, greater than or equal to about 0.02:1, greater than or equal to about 0.03:1, greater than or equal to about 0.04:1, greater than or equal to about 0.05:1, greater than or equal to about 0.06:1, greater than or equal to about 0.07:1, greater than or equal to about 0.08:1, greater than or equal to about 0.09:1, greater than or equal to about 0.1:1, greater than or equal to about 0.2:1, greater than or equal to about 0.3:1, greater than or equal to about 0.4, or greater than or equal to about 0.5:1. The ratio of the line width of the conductive wiring 121 to the thickness of the passivation layer 170 may be less than or equal to about 2.9:1, less than or equal to about 2.7:1, less than or equal to about 2.6:1, less than or equal to about 2.5:1, less than or equal to about 2.4:1, less than or equal to about 2.2:1, less than or equal to about 2.0:1, less than or equal to about 1.9:1, less than or equal to about 1.7:1, less than or equal to about 1.6:1, less than or equal to about 1.5:1, less than or equal to about 1.4:1, less than or equal to about 1.3:1, less than or equal to about 1.2:1, less than or equal to about 1.1:1, less than about 1:1. Additionally, the ratio of the thickness of the passivation layer 170 to the line width of the conductive wiring 121 may be within a range combining the above numerical ranges (e.g., about 0.01 to about 1.9).

The interconnect structures 100a and 100b may further include a barrier layer 190 to prevent material diffusion of the conductive wiring 121 or a liner layer 180 to improve the adhesive strength of the conductive wiring 121. For example, the interconnect structure 100a may further include a barrier layer 190 and/or a liner layer 180 between the air gap 110A and the conductive wiring 121 or, if a passivation layer 170 is present, between the air gap 110A and the passivation layer 170. The interconnect structure 100b may further include a barrier layer 190 and/or a liner layer 180 between the dielectric layer 110 and the conductive wiring 121 or, if a passivation layer 170 is present, between the dielectric layer 110 and the passivation layer 170.

The barrier layer 190 may include a metal, a metal alloy, a metal oxide, a metal nitride, or a combination thereof.

The barrier layer 190 can prevent the materials of the conductive wiring 121 and the passivation layer 170 from diffusing into the dielectric layer 110. The barrier layer 190 may have a single-layer structure or a multi-layer structure in which multiple layers including different materials are stacked. For example, the barrier layer 190 may include a first barrier layer in contact with the conductive wiring 121 or the passivation layer 170 and a second barrier layer in contact with the dielectric layer 110, and the first barrier layer may include a metal or an alloy of metals and the second barrier layer may include a metal nitride or a metal oxide.

A metal that can be used to comprise the barrier layer 190 may be one of magnesium (Mg), aluminum (AI), scandium (Sc), titanium (Ti), vanadium (V), chromium (Cr), manganese (Mn), nickel (Ni), zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), bismuth (Bi), cobalt (Co), ruthenium (Ru), and a combination thereof. The metal alloy of the barrier layer 190 may include RuTa, IrTa, etc.

A metal oxide of the barrier layer 190 may include a compound represented by Chemical Formula 2.

MₓO_{y} Chemical Formula 2

In Chemical Formula 2,
M may be at least one of Mn, Al, Ti, Zr, Hf, Mg, Si, Ge, Y, Lu, La, Ta, and Sr, 0<x≤2, and 0<y≤3.

Examples of the metal oxide may include MnO, AlO_{z} (0<z≤3/2), TaO_{z} (0<z≤5/2), TiO₂, ZrO₂, HfO₂, MgO, SiO₂, GeO₂, Y₂O₃, Lu₂O₃, La₂O₃, SrO, etc.

A metal nitride of the barrier layer 190 may include tantalum nitride (TaN), titanium nitride (TiN), ruthenium nitride (RuN), tungsten nitride (WN), aluminum nitride (AlN), IrTaN, TiSiN, and the like.

A barrier layer 190 can be formed through a deposition process including chemical vapor deposition (CVD), plasma enhanced chemical vapor deposition (PECVD), physical vapor deposition (PVD), atomic layer deposition (ALD), sputtering, and plating used in general semiconductor manufacturing processes.

A thickness of the above barrier layer 190 may be about 1 nm to about 40 nm. Within the above range, the barrier layer 190 may have a thickness of less than or equal to about 30 nm, for example, less than or equal to about 25 nm, less than or equal to about 20 nm, less than or equal to about 15 nm, less than or equal to about 10 nm, less than or equal to about 9 nm, less than or equal to about 8 nm, less than or equal to about 7 nm, or less than or equal to about 6 nm, and greater than or equal to about 1 nm.

A liner layer 180 may be further included between the conductive wiring 121 and the barrier layer 190 or, if there is a passivation layer 170, between the passivation layer 170 and the barrier layer 190. The liner layer 180 can be formed through a deposition process including chemical vapor deposition (CVD), plasma enhanced chemical vapor deposition (PECVD), physical vapor deposition (PVD), atomic layer deposition (ALD), sputtering, and plating used in general semiconductor manufacturing processes.

The liner layer 180 may include a metal, a metal alloy, a metal nitride, or the like. For example, the liner layer 180 may include Ta, Ti, Co, TaN, Ti(Si)N, or W. However, the present disclosure is not limited thereto. The liner layer 180 may include a single-layer structure or a multi-layer structure in which different materials are stacked. The thickness of the liner layer 180 may vary depending on the deposition process as well as the material used.

A thickness of the liner layer 180 may be from about 1 nm to about 40 nm. Within the above range, the liner layer 180 may have a thickness of less than or equal to about 30 nm, for example, for example about 25 nm, less than or equal to about 20 nm, less than or equal to about 15 nm, less than or equal to about 10 nm, less than or equal to about 9 nm, less than or equal to about 8 nm, less than or equal to about 7 nm, or less than or equal to about 6 nm and greater than or equal to about 1 nm.

In FIG. 4, the passivation layer 170, the liner layer 180, and the barrier layer 190 are all illustrated, but these layers may be optionally arranged (present) as needed, and at least one of these layers may be omitted.

The interconnect structures 100a and 100b includes a plurality of interconnect lines and a via 150 connecting a lower interconnect line 120, and an upper interconnect line 120ₙ₊₁, and the via 150 may include the metal compound of Chemical Formula 1. As the line width of the conductive wiring 121 is reduced, the dimension of the via 150 is also reduced. Therefore, when the metal compound of Chemical Formula 1 is used, the increase in resistance due to the decrease in the size of the via 150 can be prevented or reduced.

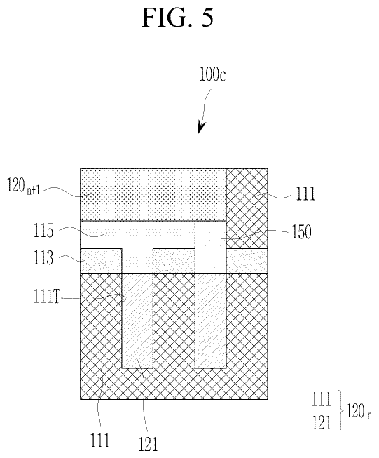

An interconnect structure according to another embodiment is described below with reference to FIG. 5. Referring to FIG. 5, the interconnect structure 100c includes a first dielectric layer 111 having a trench structure 111T; a conductive wiring 121 including the metal compound represented by Chemical Formula 1 within the trench structure 111T, and
a second dielectric layer 113 selectively disposed on the first dielectric layer 111,
wherein the trench structure 111T has a line width of less than or equal to about 10 nm and an aspect ratio of greater than or equal to about 3.

The interconnect structure 100c may be provided on a substrate (not shown) to constitute an electronic device. For example, the electronic device may include a DRAM or a logic device, and in this case, the interconnect structure 100c may be applied to a BEOL (Back End Of Line) structure of the DRAM or the logic device. In addition, the interconnect structure 100c can be applied to various electronic devices.

The substrate may be a semiconductor substrate, as described in FIGS. 1 and 2.

The first dielectric layer 111 can be formed on the substrate. This first dielectric layer 111 may have a single-layer structure or a multi-layer structure in which different materials are stacked. The first dielectric layer 111 may be an intermetallic dielectric (IMD) layer. The material and manufacturing method constituting the first dielectric layer 111 are the same as those described for the dielectric layer 110 of FIGS. 1 and 2.

The trench structure 111T can be formed in the first dielectric layer 111 to a predetermined depth. Such a trench structure 111T can be formed, for example, through a photolithography process and an etching process.

The trench structure 111T may have a line width of less than or equal to about 10 nm, for example, less than or equal to about 9 nm, less than or equal to about 8 nm, less than or equal to about 7 nm, or less than or equal to about 6 nm and greater than or equal to about 1 nm. The trench structure 111T may have an aspect ratio of greater than or equal to about 3, for example, greater than or equal to about 4, greater than or equal to about 5, greater than or equal to about 6. Here, the aspect ratio means the depth of the trench structure 110T divided by the width.

The trench structure 111T may be completely or partially filled with the metal compound of Chemical Formula 1 to provide a conductive wiring 121.

A second dielectric layer 113 may be selectively disposed on the upper surface of the first dielectric layer 111. The second dielectric layer 113 may have a single-layer structure or a multi-layer structure in which different materials are stacked.

The first dielectric layer 111 may include a first dielectric having a dielectric constant of less than or equal to about 3.6, and the second dielectric layer 113 may include a second dielectric different from the first dielectric.

The second dielectric may include a dielectric material having different dielectric constants. For example, the second dielectric may include AlO_{z} (0<z≤3/2, for example, Al₂O₃), AlN, ZrOₓ (0<x≤2), HfOₓ (0<x≤2), SiO₂, SiCO, SiCN, SiON, SICOH, AlSiO, BN, or a combination thereof, but is not limited thereto.

A third dielectric layer 115 may be disposed on an upper surface of the second dielectric layer 113 and/or the conductive wiring 121, and the third dielectric layer 115 may be an interlayer insulating layer.

The third dielectric layer 115 may include the same dielectric material as the first dielectric layer 111.

The interconnect structure 100c may further include a cap layer (not shown) on the upper portion of the conductive wiring 121. This cap layer can reduce the resistance of the conductive wiring 121 and/or prevent electrical deterioration of the conductive wiring 121. The cap layer may be arranged to cover a portion of an upper surface of the conductive wiring 121 and/or an upper surface of the first dielectric layer 111.

The composition of the cap layer is as described in FIGS. 1 and 2.

A passivation layer may be arranged between the first dielectric layer 111 and the conductive wiring 121 along both side surfaces, and optionally, a lower surface of the trench structure 111T. The composition of the passivation layer is as described in FIGS. 1 and 2.

The interconnect structure 100c may further include a barrier layer to prevent material diffusion of the conductive wiring 121 or a liner layer to improve the adhesive strength of the conductive wiring 121. For example, a barrier layer may be further included between the first dielectric layer 111 and the conductive wiring 121 or, if a passivation layer is present, between the first dielectric layer 111 and the passivation layer. The composition of the barrier layer is as described in FIGS. 1 and 2.

Additionally, a liner layer may be further included between the conductive wiring 121 and the barrier layer or, if there is a passivation layer, between the passivation layer and the barrier layer. The composition of the liner layer is as described in FIGS. 1 and 2.

The interconnect structure 100c includes a plurality of interconnect lines and a via 150 connecting a lower interconnect line 120ₙ and an upper interconnect line 120ₙ₊₁, and the via 150 may include the metal compound of Chemical Formula 1.

Hereinafter, a method for manufacturing an interconnect structures 100a and 100b according to FIGS. 1 and 2 is described.

A first dielectric layer 110 having a trench structure 110T is provided;
after adding a metal (M), or a metal (M)-containing precursor, to the trench structure 110T, the trench structure 110T is heated to a reaction temperature;
an X-containing precursor is added under an inert atmosphere to form a conductive wiring 121 including the metal compound of Chemical Formula 1; and
a portion of the dielectric layer 110 is removed to form an air gap, and a second dielectric layer is deposited to an upper portion or the first dielectric layer to provide interconnect structures 100a and 100b. The first and the second dielectric layers may be the same or different, preferably the two dielectric layers are different.

The dielectric layer 110 may be formed on a substrate through a deposition process, for example, chemical vapor deposition (CVD), plasma enhanced CVD (PECVD), spin coating, etc. The dielectric layer 110 having the trench structure 110T can be formed through a photolithography process followed by an etching process-two processes well-known to those of ordinary skill, and need not be described further herein.

After adding a metal (M) or a metal (M)-containing precursor, to the trench structure 110T, the trench structure is heated to a reaction temperature, and the X-containing precursor is added under an inert atmosphere with continued heating to form a conductive wiring 121 including the metal compound of Chemical Formula 1. The reaction temperature may be determined depending on the metal compound of Chemical Formula 1. For example, when the metal compound of Chemical Formula 1 is MoP, the reaction temperature may be in a range of about 400° C. to about 900° C. The pressure in the reaction chamber during the reaction can be from about 0.01 torr to about 100 torr. Within the above range, the pressure of the reaction chamber may be greater than or equal to about 0.05 torr, greater than or equal to about 0.1 torr, greater than or equal to about 0.5 torr, or greater than or equal to about 1 torr, and less than or equal to about 80 torr, less than or equal to about 70 torr, or less than or equal to about 60 torr. The reaction time can be from about 1 minute to about 120 minutes. Within the above range, the reaction time may be greater than or equal to about 5 minutes, greater than or equal to about 10 minutes, greater than or equal to about 30 minutes, and less than or equal to about 100 minutes.

The metal (M)-containing precursor may be selected depending on the type of the metal (M) of the Chemical Formula 1, and when M is Mo, the metal (M)-containing precursor may be MoOₓ (0<x≤3, for example, MoO₂ or MoO₃), MoS₂, MoSe₂, MoTe₂, and MoN.

The X-containing precursor may be selected depending on the type of X in Chemical Formula 1. When X is P, the X-containing precursor may be a substance composed of a single phosphorus element, such as red phosphorus, white phosphorus, or black phosphorus, PH₃, or phosphine represented by (R¹)(R₂)(R₃)P (wherein R¹, R², and R³ are each independently a C1 to C20 linear or branched alkyl group, a C1 to C20 linear or branched alkoxy group, a C1 to C20 linear or branched alkylsilyl group, a C3 to C20 cycloalkyl group, a C6 to C20 aryl group, or a combination thereof); a phosphonium salt, or a hydrate thereof; hypophosphite, or a hydrate thereof; phosphate or a hydrate thereof; or a combination thereof.

A phosphine represented by (R¹)(R₂)(R₃)P may be specifically, butylphosphine, cyclohexylphosphine, trioctylphosphine, triphenylphosphine, dimethylphenylphosphine, tri-tert-butylphosphine, dicyclohexylphenylphosphine, tricyclohexylphosphine, or diphenylphosphine, but is not limited thereto.

A phosphonium salt may be a compound including a phosphonium cation and an anion, wherein the anion may be a halogen or borate. A specific example may be tricyclohexyl phosphonium tetrafluoroborate.

A hypophosphite may include NaH₂PO₂, trimethyl phosphite, etc., and the phosphates include (NH₄)₂HPO₄, etc.

The inert atmosphere may include Ar, H₂, N₂, or a combination thereof.

The metal compound of Chemical Formula 1 generated after the reaction can expand compared to the total volume of the reactants, and the metal compound of Chemical Formula 1 existing on the upper portion of the trench structure 110T can be removed by a planarization process (e.g., chemical mechanical planarization (CMP) process).

Accordingly, when adding a metal (M) or a metal (M)-containing precursor to the trench structure 110T, because the volume of the product can be greater than the volume of the two reactants, the trench structure can be filled to about 50% to about 90%, for example, about 55% or more or about 60% or more and about 80% or less or about 70% or less of the total empty volume (space) of the trench structure 110T. The metal (M) or metal (M)-containing precursor may be filled from the lower surface of the trench structure 110T so that an empty space may exist at the top, or the two side surfaces and the lower surface along walls of the trench structure 110T may be filled so that an empty space exists at the center of the trench structure.

In another embodiment, the conductive wiring 121 including the metal compound of Chemical Formula 1 may be formed by depositing a metal (M)-containing precursor and an X-containing precursor into the inside of the trench structure 110T under an inert atmosphere with heating to an appropriate reaction temperature as described above.

Again, as above, the metal compound of Chemical Formula 1 generated after the reaction can expand compared to the volume of the reactants, and the metal compound of Chemical Formula 1 existing on the upper portion of the trench structure 110T can be removed by a planarization process (e.g., chemical mechanical planarization (CMP) process).

When filling the inside of the trench structure 110T with a metal (M)-containing precursor and an X-containing precursor, the metal compound of Chemical Formula 1 may expand upon generation, so that it may be filled to fill about 60% to about 95% of the total volume (space) of the trench structure 110T. The metal (M)-containing precursor and X-containing precursor may be filled from the lower surface of the trench structure 110T so that an empty space may exist at the top, or the two side surfaces and the lower surface along walls of the trench structure 110T may be filled so that an empty space exists at the center of the trench structure.

The metal (M)-containing precursor, the X-containing precursor, and the inert atmosphere are as described above. Additionally, the reaction temperature, the pressure in the reaction chamber during the reaction, and the reaction time are as described above.

After forming the conductive wiring 121, all or a portion of the dielectric layer 110 can be removed to form an air gap 110A. The air gap 110A may be formed by etching a portion of the dielectric layer 110 between the conductive wiring 121 as in FIG. 1, or may be formed by partially etching as in FIG. 2. In the etching, a trench structure of a desired depth is formed by etching the exposed portion after forming a photoresist pattern, and then an upper dielectric layer (interlayer insulating layer) is formed without filling the trench structure so that an air gap 110A may be formed. The etching may be dry or wet etching.

In another embodiment, the interconnect structure 100a illustrated in FIG. 1 may be manufactured by reacting a metal (M)-containing precursor and an X-containing precursor to provide a conductive layer 110 as a thin film including the metal compound represented by Chemical Formula 1, patterning the conductive thin film, and then forming an upper dielectric layer to form an air gap 110A.

Hereinafter, a method for manufacturing an interconnect structure 100c according to FIG. 5 is described.

First, a first dielectric layer 111 having a trench structure 111T is provided,
after adding a metal (M), or a metal (M)-containing precursor, to the trench structure 111T, the trench structure 111T is heated to a reaction temperature,
an X-containing precursor is added under an inert atmosphere to form a conductive wiring 121 including the metal compound of Chemical Formula 1, and
a second dielectric layer 113 is selectively positioned and formed on an upper portion of the first dielectric layer 111, manufacturing an interconnect structure 100c.

In another embodiment, a conductive wiring 121 including the metal compound of Chemical Formula 1 may be formed by depositing a metal (M)-containing precursor and an X-containing precursor into the trench structure 111T under an inert atmosphere. The metal (M)-containing precursor, the X-containing precursor, and the inert atmosphere are as described above. Additionally, the reaction temperature, the pressure in the reaction chamber during the reaction, and the reaction time are as described above.

The metal compound of Chemical Formula 1 generated after the reaction can expand compared to the volume of the reactants, and the metal compound of Chemical Formula 1 existing on the upper portion of the trench structure 111T can be removed by a planarization process (e.g., chemical mechanical planarization (CMP) process).

When filling the inside of the trench structure 111T with a metal (M) or a metal (M)-containing precursor, the metal compound of Chemical Formula 1 may expand upon generation, so that it may be filled to fill about 60% to about 95% of the total volume inside the trench structure 111T. The metal (M) or metal (M)-containing precursor may be filled from the lower surface of the trench structure 111T so that an empty space may exist at the top, or the two side surfaces and the lower surface along walls of the trench structure 111T may be filled so that an empty space exists at the center.

In another embodiment, a conductive wiring 121 including the metal compound of Chemical Formula 1 may be formed by depositing a metal (M)-containing precursor and an X-containing precursor into the trench structure 111T under an inert atmosphere and then heated to a reaction temperature to form the conductive wiring 121.

The metal compound of Chemical Formula 1 generated after the reaction can expand compared to the volume of the reactants, and the metal compound of Chemical Formula 1 existing on the upper portion of the trench structure 111T may be removed by a planarization process (e.g., chemical mechanical planarization (CMP) process).

When filling the inside of the trench structure 111T with a metal (M)-containing precursor and an X-containing precursor, the metal compound of Chemical Formula 1 may expand upon generation, so that the trench structure may be filled to about 60% to about 95% of the total volume inside the trench structure 111T. The metal (M)-containing precursor and X-containing precursor may be filled from the lower surface of the trench structure 111T so that an empty space may exist at the top, or the two side surfaces and the lower surface along walls of the trench structure 111T may be filled so that an empty space exists at the center.

The metal (M)-containing precursor, the X-containing precursor, and the inert atmosphere are as described above. Additionally, the reaction temperature, the pressure in the reaction chamber during the reaction, and the reaction time are as described above.

An interconnect structure 100c is manufactured by selectively forming a second dielectric layer 113 on an upper portion of the first dielectric layer 111. The second dielectric layer 113 can be formed through a deposition process, for example, chemical vapor deposition (CVD), plasma enhanced CVD (PECVD), spin coating, etc.

The aforementioned interconnect structures 100a, 100b, and 100c can alleviate an increase in electrical resistance due to a decrease in the line width of wiring due to high integration of semiconductor devices. Moreover, the interconnect structure may exhibit a reduction in defects caused by electromigration due to an increase in electrical resistance within the interconnect structure.

The aforementioned interconnect structures 100a, 100b, and 100c can be used to provide electronic devices. For example, the electronic device may include a semiconductor device, in which case the interconnect structures 100a, 100b, and 100c may be applied to a BEOL (Back End Of Line) structure of the semiconductor device, etc. The semiconductor device may include at least one of a transistor, a capacitor, a diode, and a resistor. In addition, the interconnect structures 100a, 100b, 100c, 200a, 200b, 200c, 200d, and 300 can be applied to various electronic devices.

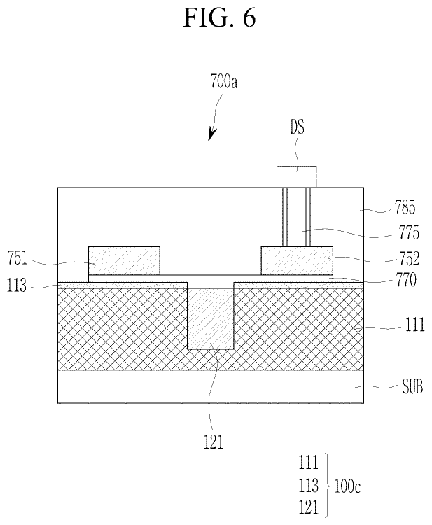

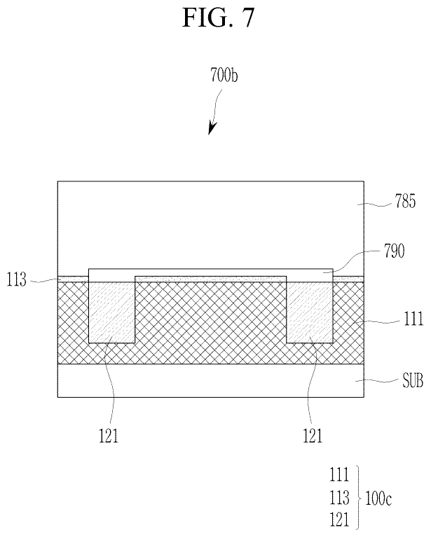

Hereinafter, an electronic device including the interconnect structures described above will be described with reference to FIGS. 6 and 7.

FIGS. 6 and 7 are cross-sectional views of electronic components according to some embodiments.

Referring to FIG. 6, in an embodiment, the electronic device 700a may be formed of a transistor connected to data storage DS. An electronic component 700a may include a substrate SUB, a first dielectric layer 111, a conductive wiring 121 is present in a trench structure of the first dielectric layer 111, and a second dielectric layer 113 is present on the upper portion of the first dielectric layer 111. The aforementioned conductive wiring 121, first dielectric layer 111, and second dielectric layer 113 are formed in the same structure as the interconnect structure 100c illustrated in FIG. 5. FIG. 6 illustrates an electronic device in which the interconnect structure 100c illustrated in FIG. 5 is arranged, but the interconnect structures 100a and 100b illustrated in FIGS. 1 to 4 may also be applied in the same manner.

The gate insulating layer 770 is formed on the second dielectric layer 113 and the conductive wiring 121. A source electrode 751 and a drain electrode 752 are arranged spaced apart from each other on the gate insulating layer 770. The conductive wiring 121 can be configured to operate as a gate electrode of the electronic element 770a.

The electronic device 700a may further include an insulating layer 785, such as silicon oxide, covering the source electrode 751, the gate insulating layer 770, and the drain electrode 752, and a data storage (DS) (e.g., a capacitor) may be on the insulating layer 785. Contact 775 including an electrically conductive material such as a metal or a metal alloy may connect data storage DS and drain electrode 752.

Referring to FIG. 7, in an embodiment, the electronic device 700b different from the electronic device 700a shown in FIG. 6 in that the gate insulating layer 770, the contact 775, the source electrode 751, the drain electrode 752, and the data storage DS are omitted. Additionally, the first dielectric layer 111 includes two trenches spaced apart from each other, and each of the trenches is formed in the same structure as the interconnect structure in FIG. 5. FIG. 6 illustrates an electronic device in which the interconnect structure 100c of FIG. 5 is arranged, but the interconnect structures 100a and 100b illustrated in FIGS. 1 and 2 can also be applied in the same manner.

An upper conductive layer 790 is formed on the second dielectric layer 113 and contacts the upper portion of the conductive wiring 121 in each interconnect structure, so that the interconnect structures can be electrically connected to each other. The upper conductive layer 790 may include a conductive material such as a metal, a metal alloy, or a doped semiconductor.

Hereinafter, the embodiments are illustrated in more detail with reference to examples. However, the following examples are for illustrative purposes only and do not limit the scope of the rights.

### Example 1: Manufacturing of Stacked Structure

Mo is deposited on a Si(001) (thickness: 650 μm)/SiO₂ (thickness: 100 nm) substrate, the temperature is increased to 800° C., and red phosphorus is supplied for 1 hour to synthesize MoP. A stacked structure is manufactured by forming a MoP thin film (thickness: 15 nm).

### Example 2: Manufacturing of Stacked Structure

Mo is deposited on a sapphire substrate (thickness: 650 μm), the temperature is increased to 800° C., and red phosphorus is supplied for 1 hour to synthesize MoP. A stacked structure is manufactured by forming a MoP thin film (thickness: 15 nm).

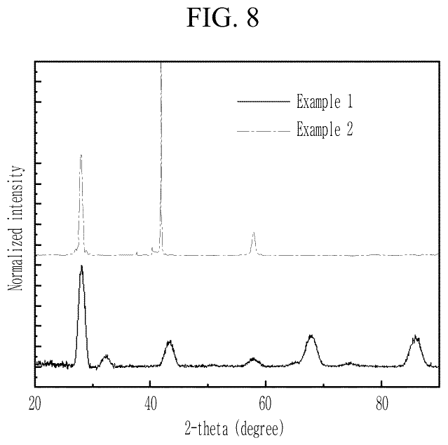

X-ray diffraction spectra analysis (light source: Cu Kα) of the stacked structures according to Examples 1 and 2 is conducted and shown in FIG. 8. FIG. 8 is a X-ray diffraction spectra analysis of stacked structures according to Examples 1 and 2. Referring to FIG. 8, the stacked structures according to Examples 1 and 2 include MoP.

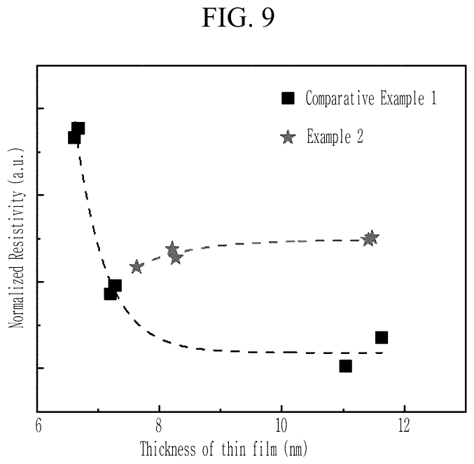

The resistance according to the film thickness of the stacked structure in which the MoP thin film was formed on a sapphire substrate (thickness: 650 μm) using the same method as in Example 2 and the stacked structure according to Comparative Example 1 in which Mo is deposited on a sapphire substrate (thickness: 650 μm) is measured, and the results are shown in FIG. 9. FIG. 9 is a plot showing the results of evaluating resistance according to the film thickness of the stacked structure according to Example 2 and the stacked structure according to Comparative Example 1. Referring to FIG. 9, the resistance of the stacked structure according to Example 2 does not increase even if the thickness is reduced compared to the stacked structure according to Comparative Example 1.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

Description of symbols
100a, 100b, 100c: interconnect structure

| | |
|---|---|
| SUB: substrate | 121: conductive wiring |
| 110A: air gap | 110T: trench structure |
| 110: dielectric layer | 111: first dielectric layer |
| 113: second dielectric layer | |
| 120ₙ, 120_{n + 1}: interconnect line | |
| 700a, 700b: electronic device | |
| 770: gate insulating layer | 751: source electrode |
| 752: drain electrode | DS: data storage |
| 785: insulation layer | 790: upper conductive layer |

What is claimed is:

1. An interconnect structure, comprising
a dielectric layer including a trench structure; a conductive wiring including a metal compound represented by Chemical Formula 1 disposed within the trench structure; and an air gap disposed between the conductive wiring,
wherein the trench structure has a line width of less than or equal to about 10 nm and an aspect ratio of greater than or equal to about 3:
MXₐ Chemical Formula 1
wherein, in Chemical Formula 1,
M is at least one metal of Zr, Nb, Cu, Ru, Al, Co, W, Mo, Ti, Ta, Ni, Pt, Cr, Rh, Ir, Pd, or Os, X is at least one element of C, N, P, As, S, Se, or Te, and a is a number determined by the stoichiometry of M and X.

2. The interconnect structure of claim 1, wherein
the dielectric layer comprises a dielectric with a dielectric constant of less than or equal to about 3.6.

3. The interconnect structure of claim 1, wherein
the dielectric layer comprises AlO_{z} (0<z≤3/2), AlN, ZrOₓ (0<x≤2), HfOₓ (0<x≤2), SiO₂, SiCO, SiCN, SION, SiCOH, AlSiO, BN, or a combination thereof.

4. The interconnect structure of claim 1, wherein
a width of the air gap is in a range of about 2 nm to about 12 nm.

5. The interconnect structure of claim 1, wherein
a depth of the air gap is equal to or less than a depth of the conductive wiring.

6. The interconnect structure of claim 1, wherein
the air gap disposed between the conductive wiring is positioned in the dielectric layer between the conductive wiring.

7. The interconnect structure of claim 1, wherein
a ratio of the width of the air gap to the line width of the conductive wiring is about 1.1:1 to about 4:1.

8. The interconnect structure of claim 1, wherein
the interconnect structure further comprises a cap layer on an upper portion of the conductive wiring.

9. The interconnect structure of claim 1, wherein
the interconnect structure further comprises a barrier layer, a liner layer, or a combination thereof, on at least a surface of the trench structure between the dielectric layer and the conductive wiring.

10. The interconnect structure of claim 1, further comprising a plurality of interconnect lines and a via connecting a lower interconnect line and an upper interconnect line, and the via comprises a metal compound of Chemical Formula 1.

11. An interconnect structure, comprising
a first dielectric layer including a trench structure;
a conductive wiring including a metal compound represented by Chemical Formula 1 disposed within the trench structure; and
a second dielectric layer disposed on the first dielectric layer,
wherein the trench structure has a line width of less than or equal to about 10 nm and an aspect ratio of greater than or equal to about 3:
MXₐ Chemical Formula 1
wherein, in Chemical Formula 1,
M is at least one metal of Zr, Nb, Cu, Ru, Al, Co, W, Mo, Ti, Ta, Ni, Pt, Cr, Rh, Ir, Pd, or Os, X is at least one element of C, N, P, As, S, Se, or Te, and a is a number determined by the stoichiometry of M and X.

12. The interconnect structure of claim 11, wherein
the first dielectric layer comprises a first dielectric with a dielectric constant of less than or equal to about 3.6, and the second dielectric layer comprises a second dielectric different from the first dielectric.

13. The interconnect structure of claim 11, wherein
the first dielectric layer comprises AlO_{z} (0<z≤3/2, for example, Al₂O₃), AlN, ZrOₓ (0<x≤2), HfOₓ (0<x≤2), SiO₂, SiCO, SiCN, SION, SiCOH, AlSiO, BN, or a combination thereof.

14. The interconnect structure of claim 11, wherein
the interconnect structure further comprises a cap layer on an upper portion of the conductive wiring.

15. The interconnect structure of claim 11, wherein
the interconnect structure further comprises a barrier layer, a liner layer, or a combination thereof, on at least a surface of the trench structure between the first dielectric layer and the conductive wiring.

16. The interconnect structure of claim 11, further comprising a plurality of interconnect lines and a via connecting a lower interconnect line and an upper interconnect line, and the via comprises the metal compound of Chemical Formula 1.

17. A method for manufacturing an interconnect structure, comprising
i. providing a first dielectric layer including a trench structure;
ii a. adding a metal (M), or a metal (M)-containing precursor, within the trench structure, heating the metal or metal-containing precursor to a reaction temperature, and adding an X-containing precursor under an inert atmosphere to the metal or metal-containing precursor to form a conductive wiring including a metal compound of Chemical Formula 1, or
ii b. adding a metal (M)-containing precursor and an X-containing precursor within the trench structure under an inert atmosphere, and heating the metal-containing precursor and the X-containing precursor to a reaction temperature to form a conductive wiring including a metal compound of Chemical Formula 1; and
iii. removing all or a portion of the dielectric layer to form an air gap:
MXₐ Chemical Formula 1
wherein, in Chemical Formula 1,
M is at least one metal of Zr, Nb, Cu, Ru, Al, Co, W, Mo, Ti, Ta, Ni, Pt, Cr, Rh, Ir, Pd, or Os, X is at least one element of C, N, P, As, S, Se, or Te, and a is a number determined by the stoichiometry of M and X.

18. The method of claim 17, further comprising
forming the second dielectric layer on an upper portion of the first dielectric layer.

19. An electronic device comprising the interconnect structure of claim 1.

20. The electronic device of claim 19, wherein
the electronic device comprises a transistor, a capacitor, a diode, or a resistor.
